(19) United States
(12) Patent Application Publication
(10) Pub. No.: US 2026/0040433 A1
(43) Pub. Date: Feb. 5, 2026

(54) OPTIMIZED TABBED ROUTING

(71) Applicant: DELL PRODUCTS L.P., Round Rock, TX (US)

(72) Inventors: Chun-Lin Liao, Taipei (TW); Bing-Jia Zhong, Taipei City (TW); Chang-Kai Chu, Zhongli District (TW); Bhyrav Mutnury, Round Rock, TX (US)

(21) Appl. No.: 18/788,873

(22) Filed: Jul. 30, 2024

(51) Int. Cl. H05K 1/02

(52) U.S. Cl. CPC H05K 1/0245; H05K 2201/09263

(57) ABSTRACT

An information handling system includes a printed circuit board, which in turn includes a coupled differential trace pair with a tabbed routing. The coupled differential trace pair includes a differential trace pair. The differential trace pair includes a trace, and the trace includes a skew compensation structure at a portion of the trace before the tabbed routing.

### FIELD OF THE DISCLOSURE

The present disclosure generally relates to information handling systems, and more particularly relates to optimized tabbed routing.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An information handling system includes a printed circuit board, which in turn includes a coupled differential trace pair with a tabbed routing. The coupled differential trace pair includes a differential trace pair. The differential trace pair includes a trace, which in turn includes a skew compensation structure at a portion of the trace before the tabbed routing.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of an information handling system for optimized tabbed routing, according to an embodiment of the present disclosure;

FIGS. 2-7 are diagrams of a printed circuit board for optimized tabbed routing, according to an embodiment of the present disclosure;

FIG. 8 is a flowchart of a method for optimized tabbed routing, according to an embodiment of the present disclosure;

FIG. 9 is a graph of a far-end crosstalk for optimized tabbed routing, according to an embodiment of the present disclosure; and

FIG. 10 is a block diagram of an information handling system, according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

Information handling systems, such as switches, servers, and/or other computing devices typically include circuit boards with high-speed communication traces that are connected to different subsystems in order to provide for the transmission of information between those subsystems. For example, a differential trace pair may be provided between a transmitter subsystem and a receiver subsystem in the switch or server (or between different switches and/or servers) in order to allow those subsystems to transmit and receive information. Several issues associated with the routing of differential trace pairs may be due to various factors, such as connector arrangement, placement of the differential trace pair, the angle of routing, etc. One of the issues is skew, which typically results when one of the traces in a differential trace pair is longer than the other. This mismatch of trace length may cause common node noise where a signal sent from the transmitter subsystem on the shorter trace in the differential trace pair arrives at the receiving subsystem before the signal that was sent from the transmitter subsystem on the longer trace in the differential trace pair arrives. This issue is amplified as signal speeds increase beyond 25 gigabits per second (Gbps).

Another issue associated with the routing of differential trace pairs is crosstalk. Crosstalk is a phenomenon in which signal integrity is compromised when adjacent differential trace pairs are switching and noise from one differential trace pair couples to an adjacent differential trace pair. For example, if we route high-speed differential traces in close proximity due to routing density, then traces start to exhibit higher crosstalk. Tabbed routing was introduced as an option to minimize crosstalk. However, at higher speeds, tab routing may not be effective. Thus, the present disclosure provides a system and method to optimize the tabbed routing, such that it is effective even at higher speeds.

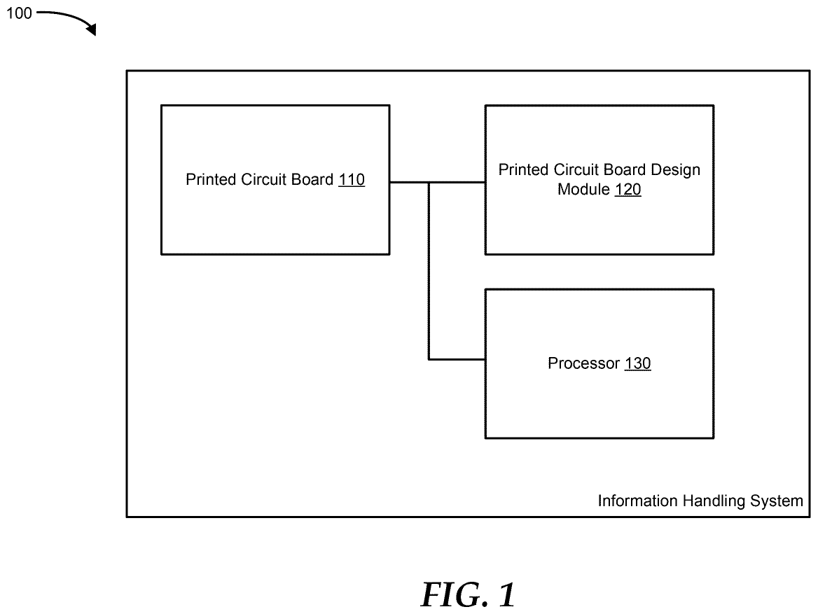

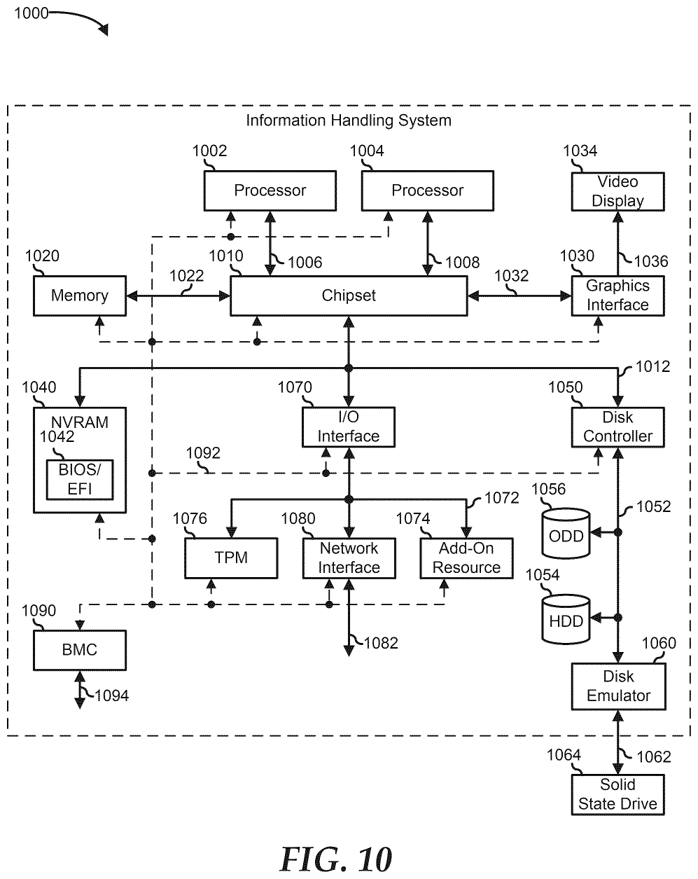

FIG. 1 shows a portion of an information handling system 100, according to an embodiment of the present disclosure. Information handling system 100, which is similar to information handling system 1000 of FIG. 10, includes a printed circuit board (PCB) 110, a PCB design module 120, and a processor 130. Processor 130 may be coupled to PCB 110 and PCB design module 120. However, other connections between these and other components of information handling system 100 may be omitted for descriptive clarity.

Although not specifically shown, information handling system 100 may include more than one PCB. For example, one or more components of information handling system 100 may be implemented using hardware circuitry on one or more PCBs. The hardware circuitry may include components soldered onto the PCB, as well as conductive traces etched into a conductive layer of the PCB. For example, a PCB may include multiple conductive layers, each comprising conductive traces for carrying current and traces for carrying data signals of various data signal types, including high-speed data signals. In various embodiments, the conductive layers may be distributed on respective sides of one or more substrate layers of the PCB or between alternating substrate layers of the PCB. For example, the PCB may be single-sided, double-sided, or multi-layered. A PCB may couple two or more devices to one another. For example, the PCB may include one or more traces that couple two or more devices to one another. In some embodiments, traces in a first conductive layer may be coupled to traces in a second conductive layer using one or more vias.

High-speed information transmission typically uses differential signaling techniques that operate to transmit information from a sender device using two complementary signals that provide the same signal as a “differential pair” of traces. The use of differential trace pairs has traditionally minimized crosstalk. However, as the transmission speeds over differential trace pairs have increased, problems associated with crosstalk have become more and more prevalent. In addition, microstrip structures are known to exhibit higher amounts of far-end crosstalk. In order to avoid crosstalk, differential trace pairs are typically spaced as far apart as possible. For example, as a general rule is to space the differential trace pairs by a distance of at least five times the thickness of their dielectric. However, as printed circuit boards have become denser, differential trace pairs have been positioned closer and closer to each other.

As stated above, in addition to crosstalk, another challenge with high-speed data communication interfaces is skew, which can be the magnitude of time difference between two signals arriving at different intervals that ideally should arrive simultaneously. This is a concern when the signals are supposed to be synchronous, such as with differential trace pairs. Skew may be caused by one or more characteristics of a differential trace pair. For example, in addition to a length mismatch between traces, the skew may be created by routing a bend in the traces, a PCB fiber weave, or the like. In one example, the skew may be corrected by adding length to a trace in the PCB layout to match that of the longer trace, such as by using a zigzag or serpentine routing structure. Other mechanisms, such as switchback routing may be used to compensate for the skew. Another way to compensate for the skew is by flipping the polarity at the receiver subsystem end of the differential trace pair such that the shorter trace leaving the transmitter subsystem end of the differential trace pair becomes the longer trace entering the receiver subsystem end of the differential trace pair.

PCB design module 120 may be configured to facilitate a design layout or routing of traces and connections of PCBs in an information handling system, such as in information handling system 100. For example, PCB design module 120 may be configured to facilitate the routing of high-speed traces to minimize skew and/or crosstalk. As such, PCB design module 120 may be configured to identify or predict the skew. For example, an internal structure of PCB 110 may be modeled by PCB design module 120 and perform an electromagnetic analysis. PCB 110 may execute a simulation process of high-speed signal propagation in a PCB. PCB 110 may then analyze a propagation delay time difference or skew at differential trace pairs in PCB 110. In one example, a vector network analyzer may be used to measure S-parameters over different operating conditions. Based on the analysis, PCB design module 120 may calculate the skew.

Based on the predicted skew, PCB design module 120 may determine how to adjust or compensate for the skew based on the modeling and/or simulation performed at the factory setting prior to finalizing the design of the PCB. PCB design module 120 may determine one or more sources of the skew in order to identify how to address it. For example, when the skew is induced by the construction of the PCB substrate material, then PCB design module 120 may recommend mechanically spreading glass weaves. In another example, when the skew is induced by impedance deviation due to length disparity, then a length tuning structure, which is a skew compensation structure, may be applied to one side of the differential trace pair. Other skew compensation structures to compensate for the skew include increasing the width of one of the traces of the differential trace pair. In addition, the spacing between the traces may be increased.

In addition, PCB design module 120 may determine a location for the skew compensation mechanism. In particular, PCB design module 120 may determine whether to compensate for the skew before or after a tabbed routing structure. The analysis and compensation are performed to optimize the routing of the high-speed differential traces and to achieve the best possible signal quality within certain physical limits of the PCB. Processor 110, which is similar to processors 1002 and 1004 of FIG. 10, may perform the above or any suitable operations including but not limited to PCB design module 120.

Although the examples shown herein are microstrip differential trace pairs, one of skill in the art will appreciate that the present disclosure may include stripline differential trace pairs or other differential trace pair structures instead without varying from the scope of the present disclosure. Those of ordinary skill in the art will appreciate that the configuration, hardware, and/or software components of information handling system 100 may vary. For example, the illustrative components within information handling system 100 are not intended to be exhaustive but rather are representative to highlight components that can be utilized to implement aspects of the present disclosure. In addition, other devices and/or components may be used in addition to or in place of the devices/components depicted.

The depicted example does not convey or imply any architectural or other limitations with respect to the presently described embodiments and/or the general disclosure. In the discussion of the figures, reference may also be made to components illustrated in other figures for continuity of the description.

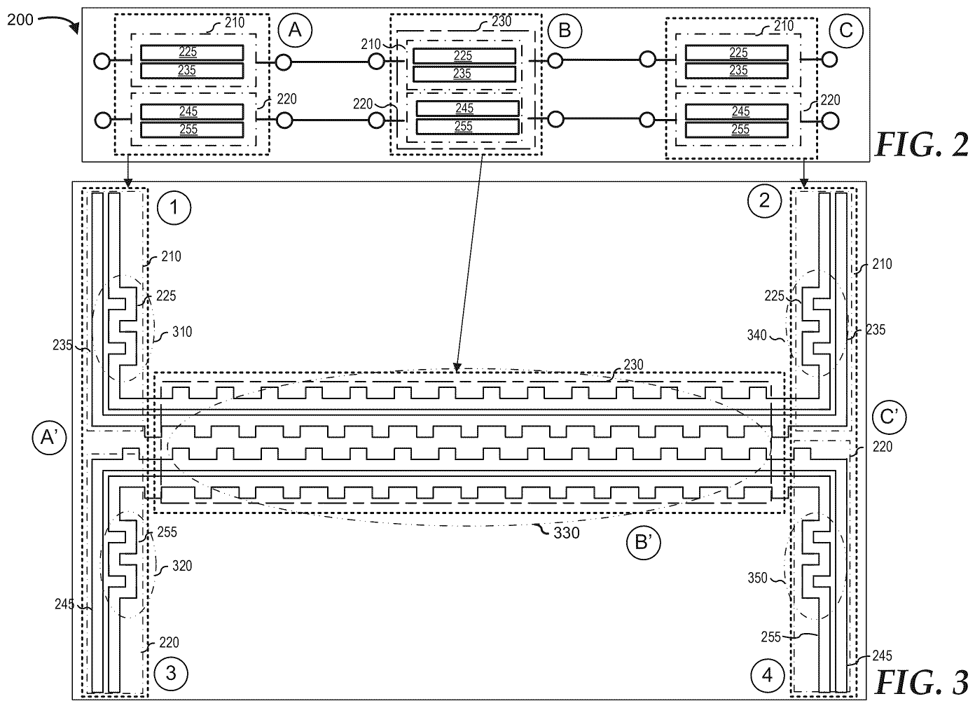

FIG. 2 illustrates a simplified diagram of a portion of a PCB 200 configured for optimized tabbed routing, according to an embodiment of the present disclosure. PCB 200, which is similar to PCB 110 of FIG. 1, may be a circuit board provided by a motherboard, a card, and/or a variety of other board or differential-trace-pair-supporting structures that would be apparent to one of skill in the art in possession of the present disclosure. PCB 200 includes a simplified view of the routing of differential trace pairs 210 and 220, according to a first-case scenario. In this scenario, skew associated with a differential trace pair may be minimized using a skew compensation structure before compensating for crosstalk via tabbed routing.

Differential trace pair 210 includes traces 225 and 235 that may be positioned adjacent to each other, such that trace 225 is located opposite trace 235. Differential trace pair 220 includes traces 245 and 255 that may be positioned adjacent to each other, such that trace 245 is located opposite trace 255. Coupled differential trace pairs 230 includes differential trace pairs 210 and 220 that may be positioned adjacent to each other, such that differential trace pair 210 is located opposite differential trace pair 220. The coupling of differential trace pairs 210 and 220 may be identified as being loosely or tightly coupled based on the spacing between the differential trace pairs.

Differential trace pairs are typically implemented in a PCB as traces on the surface of the PCB or within one or more signal layers of the PCB. Differential trace pairs may be created, formed, routed, or the like on PCB to include symmetry between its traces. Typically, electrical fields from the traces may be affected by a skew, which can affect the signal integrity of differential trace pairs. For example, the skew may be caused by a length mismatch between the traces, such as between traces 225 and 235 of differential trace pair 210 and between traces 245 and 255 of differential trace pair 220. In addition, the skew may be created by routing bends in the traces.

In this example, the routing of the differential trace pairs 210 and 220 can be divided into three sections: A, B, and C. Section A depicts a first portion associated with the routing of differential trace pairs 210 and 220. Section B depicts a second portion associated with the routing of differential trace pairs 210 and 220. In section B, differential trace pairs 210 and 220 are routed adjacent to each other as a coupled differential trace pair 230. Section C depicts a third portion of the routing of differential trace pairs 210 and 220. In this example, a signal may be transmitted from section A through section B and then through section C. Further, in this case, the skew may be compensated in section A prior to the signal movement through section B. In addition, the skew may also be compensated in section C.

FIG. 3 illustrates a more detailed view of PCB 200, according to an embodiment of the present disclosure. As stated above, PCB 200 includes differential trace pairs 210 and 220 to implement a differential high-speed data communication interface. In this example, differential trace pairs are implemented as microstrip traces on the surface of PCB 200. PCB 200 includes multiple metal layers sandwiched between insulating layers. For simplicity of illustration, differential trace pairs 210 and 220 are shown as being fabricated on the surface of PCB 200 on an insulating layer, typically a prepreg layer. The prepreg layer is underlain by a metal layer that is typically a ground layer. After the top surface of PCB 200 is patterned to include differential trace pairs 210 and 220, the top surface of PCB 200 is coated with a solder mask layer, and a silkscreen pattern is printed on the solder mask layer.

Section A′, which is a detailed view of section A of FIG. 2, shows length tuning structures 310 and 320. In section A′ a length tuning structure 310 may be applied to a portion of trace 225 of differential trace pair 210. Similarly, a length tuning structure 320 may also be applied to a portion of trace 255 of differential trace pair 220. In one example, the skew may be compensated by adding length to traces 225 and 255. In this example, a first length associated with length-tuning structure 310 may be added to trace 225 while a second length associated with length-tuning structure 320 may be added to trace 255. Length tuning structures 310 and 320 may be applied to compensate for the skew identified during a simulation of data propagation in PCB 200. Simulations or lab measurements may be used to determine the first and second lengths.

Section B′, which is a detailed view of section B of FIG. 2, shows compensation tabs applied to coupled differential trace pair 230, which is also referred to as a tabbed routing 330. Tabbed routing 330 may be used to minimize crosstalk for coupled differential trace pair 230. Differential trace pairs may be deemed coupled when at least two differential trace pairs are routed adjacent to each other, based on a defined spacing.

Section C′, which is a detailed view of section C of FIG. 2, shows length tuning structures 340 and 350. In section C′ a length tuning structure 340 may be applied to a portion of trace 225 of differential trace pair 220. Similarly, a length tuning structure 350 may also be applied to a portion of trace 255 of differential trace pair 220. In one example, the skew may be compensated by adding additional length to traces 225 and 255. In this example, a third length associated with length-tuning structure 340 may be added to trace 225 while a fourth length associated with length-tuning structure 350 may be added to trace 255. Length tuning structures 340 and 350 may be applied to compensate for the skew identified during a simulation of data propagation in PCB 200. Similarly, the simulations or lab measurements may be used to determine the third and fourth lengths.

PCB 200 includes ports 1 and 2, which are input and output ports respectively of an aggressor pair. While ports 3 and 4 are input and output ports respectively of a victim pair. In this example, differential trace pair 210 may be the aggressor while differential trace pair 220 may be the victim. PCB 200 also includes an air gap between the aggressor and the victim pairs.

As would be understood by one of skill in the art, the view of PCB 200 in FIG. 3 may either be a top or bottom view. As such, the teachings of the present disclosure may be applied to microstrip structures, stripline structures, and/or other differential trace pair structures that would be apparent to one of skill in the art. In addition, one skill in the art would understand that other layers above or below the illustrated portion of PCB 200 in FIG. 3 may exist. Although the skew is compensated herein by lengthening a trace, in certain examples, the skew may be compensated by other means, such as placing another source of skew but with an opposite signature. The skew may be compensated by increasing the width of one of the traces. For example, instead of a length tuning structure, a widening structure may be used.

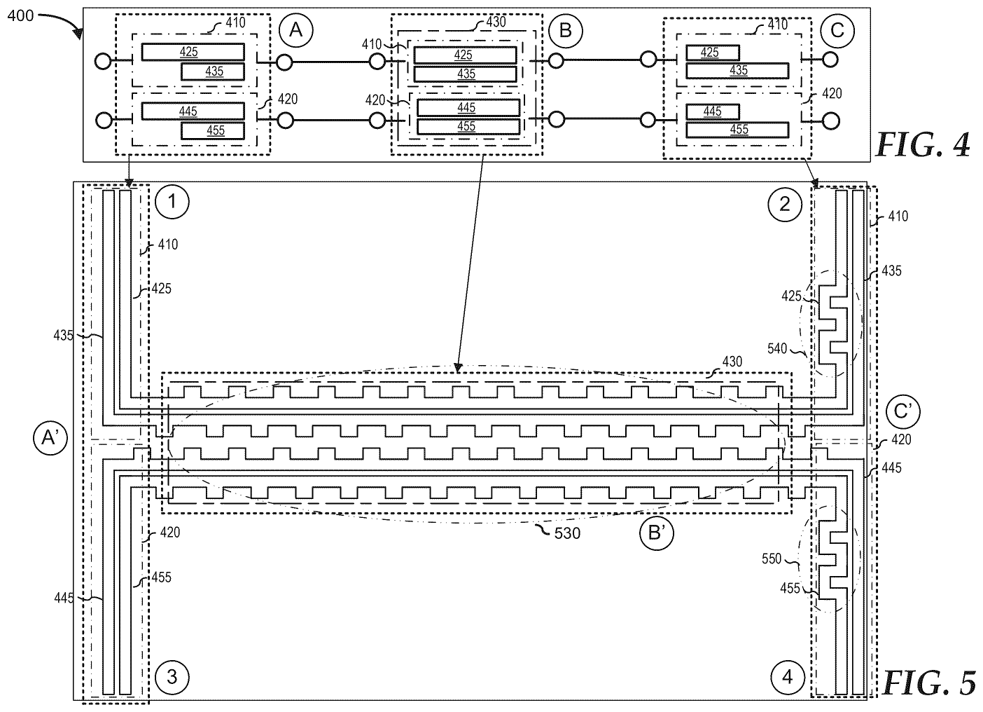

FIG. 4 illustrates a simplified diagram of a portion of a PCB 400 configured for optimized tabbed routing, according to an embodiment of the present disclosure. PCB 400 is similar to PCB 200 of FIG. 2. PCB 400 includes a simplified view of the routing of differential trace pairs 410 and 420, according to a second case scenario, wherein differential trace pairs 410 and 420 are similar to differential trace pairs 210 and 220 respectively. Differential trace pair 410 includes traces 425 and 435 that may be positioned adjacent to each other, such that trace 425 is located opposite trace 435. Differential trace pair 420 includes traces 445 and 455 that may be positioned adjacent to each other, such that trace 445 is located opposite trace 455. Coupled differential trace pair 430 includes differential trace pairs 410 and 420 that may be positioned adjacent to each other, such that differential trace pair 410 is located opposite differential trace pair 420. The coupling of differential trace pairs 410 and 420 may be identified as being loosely or tightly coupled based on the spacing between the differential trace pairs.

Similar to the above, a skew may be caused by a length mismatch between the traces, such as between traces 425 and 435 and between traces 445 and 455. In addition, the skew may be created by routing bends in the traces. Similar to the above, the routing of the differential trace pairs 410 and 420 can be divided into three sections: A, B, and C. Section A depicts a first portion associated with the routing of differential trace pairs 410 and 420. Section B depicts a second portion associated with the routing of differential trace pairs 410 and 420. In section B, differential trace pairs 410 and 420 are routed adjacent to each other as a coupled differential trace pair 430. Section C depicts a third portion of the routing of differential trace pairs 210 and 220. In this example, a signal may be transmitted from section A through section B and then through section C. In this example, the skew in section A may not be compensated prior to the signal movement through sections B and C.

FIG. 5 illustrates a more detailed view of a portion of PCB 400, according to an embodiment of the present disclosure. In one example, the skew may not be compensated in section A′ which is a detailed view of section A of FIG. 2. Section B′ which is a detailed view of section B of FIG. 2, shows compensation tabs applied to coupled differential trace pair 430, which is also referred to as a tabbed routing 530. Tabbed routing 530 may be used to minimize crosstalk for coupled differential trace pair 430. Differential trace pairs may be deemed coupled when at least two differential trace pairs are routed adjacent to each other, based on a defined spacing.

Section C′, which is a detailed view of section C of FIG. 4, shows length tuning structures 540 and 550. In section C′ a length tuning structure 540 may be applied to a portion of trace 425 of differential trace pair 420. Similarly, a length tuning structure 550 may also be applied to a portion of trace 455 of differential trace pair 420. In one example, the skew may be compensated by adding additional length to traces 425 and 455. In this example, a first length associated with length tuning structure 540 may be added to trace 425 while a second length associated with length tuning structure 550 may be added to trace 455. The first length added to trace 425 may be similar to the third length added to trace 225 of FIG. 3. Similarly, the second length added to trace 455 may be similar to the fourth length added to trace 255 of FIG. 3. Length tuning structures 540 and 550 may be applied to compensate for the skew identified during a simulation of data propagation in PCB 400. Similarly, the simulations or lab measurements may be used to determine the first and second lengths.

Similar to PCB 200, PCB 400 includes ports 1 and 2, which are input and output ports respectively of an aggressor pair. While ports 3 and 4 are input and output ports respectively of a victim pair. In this example, differential trace pair 410 may be the aggressor while differential trace pair 420 may be the victim. PCB 400 also includes an air gap between the aggressor and the victim pairs.

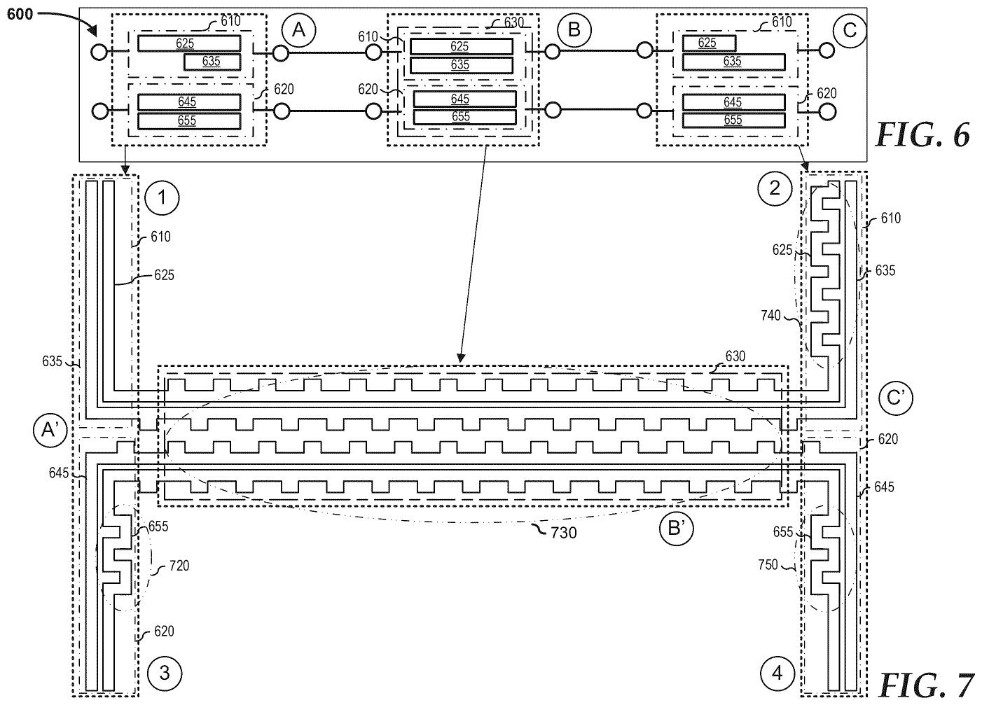

FIG. 6 illustrates a simplified diagram of a portion of a PCB 600 configured for optimized tabbed routing, according to an embodiment of the present disclosure. PCB 600 is similar to PCB 400 of FIG. 4. PCB 600 includes a simplified view of the routing of differential trace pairs 610 and 620, according to a third-case scenario, wherein differential trace pairs 610 and 620 are similar to differential trace pairs 410 and 420 respectively. Differential trace pair 610 includes traces 625 and 635 that may be positioned adjacent to each other, such that trace 625 is located opposite trace 635. Differential trace pair 620 includes traces 645 and 655 that may be positioned adjacent to each other, such that trace 645 is located opposite trace 655. Coupled differential trace pair 630 includes differential trace pairs 610 and 620 that may be positioned adjacent to each other, such that differential trace pair 610 is located opposite differential trace pair 620. The coupling of differential trace pairs 610 and 620 may be identified as either loosely or tightly coupled based on the spacing between the differential trace pairs.

Similar to the above, a skew may be caused by a length mismatch between the traces, such as between traces 625 and 635 and between traces 645 and 655. In addition, the skew may be created by routing bends in the traces. Similar to above, the routing of the differential trace pairs 610 and 620 can be divided into three sections: A, B, and C. Section A depicts a first portion associated with the routing of differential trace pairs 610 and 620. Section B depicts a second portion associated with the routing of differential trace pairs 610 and 620. In section B, differential trace pairs 610 and 620 are routed adjacent to each other as a coupled differential trace pair 630. Section C depicts a third portion of the routing of differential trace pairs 610 and 620. In this example, a signal may be transmitted from section A through section B and then through section C. In this example, the skew associated with trace 625 in section A may not be compensated prior to the signal movement through sections B and C. However, the skew associated with trace 655 in section A may be compensated. Further, the compensation for the skew in trace 625 may be doubled to address the non-compensation of trace 625 in section A.

FIG. 7 illustrates a more detailed view of a portion of PCB 600, according to an embodiment of the present disclosure. Section A′, which is a detailed view of section A of FIG. 6 shows a length tuning structure 720 applied to a portion of trace 655 of differential pair 620, similar to length tuning structure 320 of FIG. 3. Length tuning structure 720 may compensate the skew by adding a first length to trace 655. However, section A′ does not have a length tuning structure that is similar to length tuning structure 310 of FIG. 3. Accordingly, the skew associated with differential trace pair 610 at section A′ may not be compensated. Length tuning structure 720 may be applied to compensate for the skew identified during a simulation of data propagation in PCB 600. Simulations or lab measurements may be used to determine the first length.

Section B′ which is a detailed view of section B of FIG. 6, shows compensation tabs applied to coupled differential trace pair 630, which is also referred to as a tabbed routing 730. Tabbed routing 730 may be used to minimize crosstalk for coupled differential trace pair 630. Differential trace pairs may be deemed coupled when at least two differential trace pairs are routed adjacent to each other, based on a defined spacing.

Section C′, which is a detailed view of section C of FIG. 5, shows length tuning structures 740 and 750. Length tuning structure 740 may be applied to a portion of trace 625 of differential trace pair 610. In this example, the skew may be compensated by adding a second length to trace 625 via length tuning structure 740. The second length of length tuning structure 740 may be longer in comparison to the first length of length tuning structure 340 of FIG. 3. In one example, the second length of length tuning structure 740 is twice as long as the first length of length tuning structure 310 of FIG. 3 to address the non-compensation of the skew in a portion of differential trace pair 610 at section A′. Length tuning structure 750 may be applied to a portion of trace 655 to compensate for the skew by adding a third length to trace 655. The third length may be shorter than the second length. Similar to the above, length tuning structures 740 and 750 may be applied to compensate for the skew identified during a simulation of data propagation.

Similar to PCB 200, PCB 600 includes ports 1 and 2, which are input and output ports respectively of an aggressor pair. While ports 3 and 4 are input and output ports respectively of a victim pair. In this example, differential trace pair 610 may be the aggressor while differential trace pair 620 may be the victim. PCB 600 also includes an air gap between the aggressor and the victim pairs.

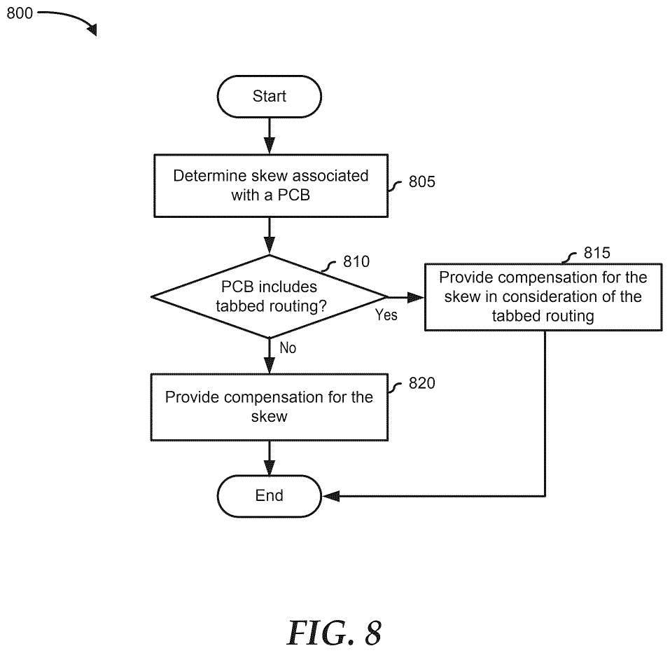

FIG. 8 illustrates a flowchart of a method 800 for optimized tabbed routing, according to an embodiment of the present disclosure. Method 800 may be performed by any suitable component of information handling system 100 including, but not limited to, PCB design module 120 of FIG. 1. While embodiments of the present disclosure are described in terms of the components of information handling system 100 of FIG. 1, it should be recognized that other components may be utilized to perform the described method. One of skill in the art will appreciate that this flowchart explains a typical example, which can be extended to applications or services in practice.

High-speed data communication interfaces are sensitive to signal skew, also simply referred to herein as skew, in the differential signal traces, and any delay mismatches between the signal traces may result in common mode conversion that leads to electro-magnetic interference issues and reduced signal quality at the signal receiver. A major contributor to the skew typically results from different lengths of the respective traces of the differential signal pair. In particular, signal traces in the PCBs are not typically laid out in straight lines, but make circuitous paths through the PCB, resulting in one of the traces of a differential trace pair traversing a longer circuit path than the other traces of the differential trace pair.

Method 800 typically starts at block 805 where a PCB design module or application may determine the skew associated with a PCB. A PCB module or application may perform an analysis of various factors that can affect the skew of the PCB. For example, the PCB design module may analyze the geometry of the traces, spacing between the traces, overall length of the traces, dielectric constant of the laminate layers that make up the PCB, and the like. If the analysis determines that the skew does not meet the design specifications, then the PCB module or application can determine which one of the various compensation mechanisms to use to improve or minimize the skew. One mechanism to compensate for the skew, also referred to as to de-skew of the differential signal, is to introduce additional length to the shorter trace. This is to slow down the signal on the shorter trace in comparison to the longer trace.

At decision block 810, the PCB design module or application may determine whether the PCB includes a tabbed routing, similar to tabbed routing 330 of FIG. 3. Tabbed routing includes tabs, also referred to as compensation tabs, is typically used to compensate for or minimize crosstalk, such as far end crosstalk (FEXT) associated with the coupled differential trace pair. For example, to reduce the FEXT on high-speed in high-density PCBs, surface tabbed routing can be used for the traces that are lying in parallel and adjacent to each other, as depicted in section B′ of FIG. 3. If the PCB includes a tabbed routing of coupled differential trace pair, then the method proceeds to block 815. If the PCB does not include a tabbed routing of coupled differential trace pair, then the method proceeds to block 820.

At block 815, the PCB design module or application may determine and provide a compensation mechanism for the skew in consideration of the tabbed routing portion of the differential trace pair. The PCB design module or application may determine the location of the tabbed routing portion of the coupled differential trace pair and apply the compensation mechanism for the skew before the tabbed routing, as depicted in length tuning structures 310 and 320 of FIG. 3 when possible. Otherwise, the PCB design module or application may apply the compensation mechanism after the tabbed routing as depicted in length tuning structures 540 and 550 of FIG. 5 and length tuning structures 740 and 750 of FIG. 7. Afterwards, the method ends.

At block 820, the PCB design module or application may determine and provide a compensation mechanism for the skew. For example, the PCB design module or application may apply a length-tuning structure at a portion of a differential trace pair. Afterwards, the method ends.

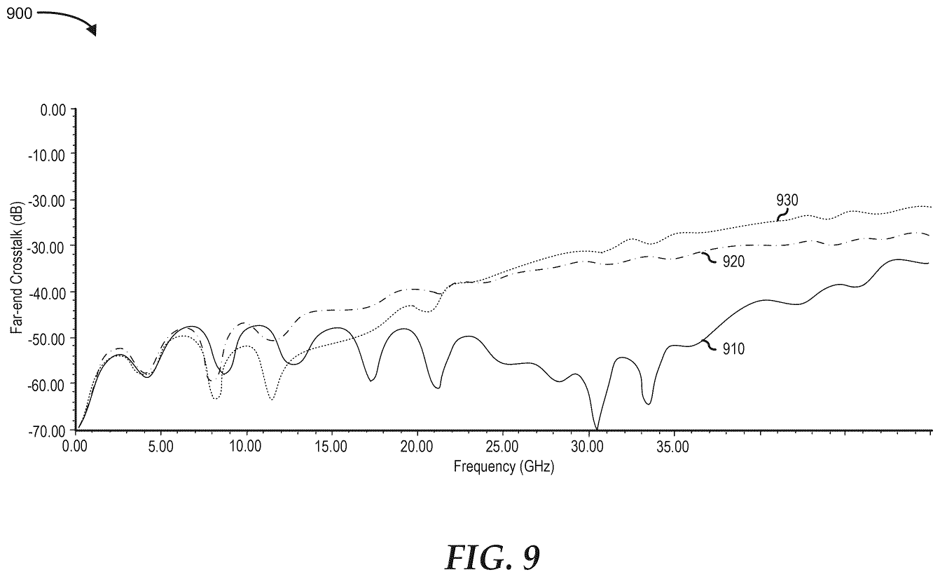

FIG. 9 illustrates a graph 900 which shows differential FEXT, according to an embodiment of the present disclosure. In particular, the differential FEXT shown is a differential mode S-parameter S_{dd41} from port 1 to port 4, as depicted in FIGS. 3, 5, and 7. S-parameters describe how sine waves interact with and scatter from an interconnect. Each interconnect has ports, which are the ends of an interconnect into which signals enter and from which they leave. Labels may be used into which a signal enters and from which the signal scatters. Crosstalk is typically expressed in decibels (dB) and varies with the frequency of the transmission, which is typically expressed in GHz. Typically, the higher the transmission, the greater the crosstalk.

Waveform 910 represents differential FEXT from port 1 to port 4 associated with the first case scenario as depicted in PCB 200 of FIGS. 2 and 3. Waveform 920 represents differential FEXT from port 1 to port 4 associated with the second case scenario depicted in PCB 400 of FIGS. 4 and 5. Waveform 930 represents differential FEXT from port 1 to port 4 associated with the third case scenario depicted in PCB 600 of FIGS. 6 and 7. Based on a comparison of waveforms 910, 920, and 930, it is shown that the differential FEXT illustrated by waveform 910 is minimal compared to the differentials FEXT illustrated by waveforms 920 and 930 at frequencies greater than 15 GHz. In particular, the differential FEXT illustrated by waveform 910 is minimized at 30 GHz. Accordingly, the first case scenario, depicted in FIGS. 2 and 3 is preferred, over the second and the third case scenarios.

FIG. 10 illustrates an embodiment of an information handling system 1000 including processors 1002 and 1004, a chipset 1010, a memory 1020, a graphics adapter 1030 connected to a video display 1034, a non-volatile RAM (NVRAM) 1040 that includes BIOS/EFI module 1042, a disk controller 1050, a hard disk drive (HDD) 1054, an optical disk drive (ODD) 1056, a disk emulator 1060 connected to a solid-state drive (SSD) 1064, an input/output (I/O) interface 1070 connected to an add-on resource 1074 and a trusted platform module (TPM) 1076, a network interface 1080, and a baseboard management controller (BMC) 1090. Processor 1002 is connected to chipset 1010 via processor interface 1006, and processor 1004 is connected to the chipset via processor interface 1008.

In a particular embodiment, processors 1002 and 1004 are connected via a high-capacity coherent fabric, such as a HyperTransport link, a QuickPath Interconnect, or the like. Chipset 1010 represents an integrated circuit or group of integrated circuits that manage the data flow between processors 1002 and 1004 and the other elements of information handling system 1000. In a particular embodiment, chipset 1010 represents a pair of integrated circuits, such as a northbridge component and a southbridge component. In another embodiment, some or all of the functions and features of chipset 1010 are integrated with one or more processors 1002 and 1004.

Memory 1020 is connected to chipset 1010 via a memory interface 1022. An example of memory interface 1022 includes a Double Data Rate (DDR) memory channel and memory 1020 represents one or more DDR Dual In-Line Memory Modules (DIMMs). In a particular embodiment, memory interface 1022 represents two or more DDR channels. In another embodiment, one or more of processors 1002 and 1004 include a memory interface that provides a dedicated memory for the processors. A DDR channel and the connected DDR DIMMs can be in accordance with a particular DDR standard, such as a DDR3 standard, a DDR4 standard, a DDR5 standard, or the like.

Memory 1020 may further represent various combinations of memory types, such as Dynamic Random Access Memory (DRAM) DIMMs, Static Random Access Memory (SRAM) DIMMs, non-volatile DIMMs (NV-DIMMs), storage class memory devices, Read-Only Memory (ROM) devices, or the like. Graphics adapter 1030 is connected to chipset 1010 via a graphics interface 1032 and provides a video display output 1036 to a video display 1034. An example of a graphics interface 1032 includes a Peripheral Component Interconnect-Express (PCIe) interface and graphics adapter 1030 can include a four-lane (×4) PCIe adapter, an eight-lane (×8) PCIe adapter, a 16-lane (×16) PCIe adapter, or another configuration, as needed or desired. In a particular embodiment, graphics adapter 1030 is provided down on a system printed circuit board (PCB). Video display output 1036 can include a Digital Video Interface (DVI), a High-Definition Multimedia Interface (HDMI), a DisplayPort interface, or the like, and video display 1034 can include a monitor, a smart television, an embedded display such as a laptop computer display, or the like.

NVRAM 1040, disk controller 1050, and I/O interface 1070 are connected to chipset 1010 via an I/O channel 1012. An example of I/O channel 1012 includes one or more point-to-point PCIe links between chipset 1010 and each of NVRAM 1040, disk controller 1050, and I/O interface 1070. Chipset 1010 can also include one or more other I/O interfaces, including a PCIe interface, an Industry Standard Architecture (ISA) interface, a Small Computer Serial Interface (SCSI) interface, an Inter-Integrated Circuit (I²C) interface, a System Packet Interface, a USB, another interface, or a combination thereof. NVRAM 1040 includes BIOS/EFI module 1042 that stores machine-executable code (BIOS/EFI code) that operates to detect the resources of information handling system 1000, to provide drivers for the resources, to initialize the resources, and to provide common access mechanisms for the resources. The functions and features of BIOS/EFI module 1042 will be further described below.

Disk controller 1050 includes a disk interface 1052 that connects the disc controller to a hard disk drive (HDD) 1054, to ODD 1056, and to disk emulator 1060. An example of disk interface 1052 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 1060 permits SSD 1064 to be connected to information handling system 1000 via an external interface 1062. An example of external interface 1062 includes a USB interface, an institute of electrical and electronics engineers (IEEE) 1394 (Firewire) interface, a proprietary interface, or a combination thereof. Alternatively, SSD 1064 can be disposed within information handling system 1000.

I/O interface 1070 includes a peripheral interface 1072 that connects the I/O interface to add-on resource 1074, to TPM 1076, and to network interface 1080. Peripheral interface 1072 can be the same type of interface as I/O channel 1012 or can be a different type of interface. As such, I/O interface 1070 extends the capacity of I/O channel 1012 when peripheral interface 1072 and the I/O channel are of the same type, and the I/O interface translates information from a format suitable to the I/O channel to a format suitable to the peripheral interface 1072 when they are of a different type. Add-on resource 1074 can include a data storage system, an additional graphics interface, a network interface card (NIC), a sound/video processing card, another add-on resource, or a combination thereof. Add-on resource 1074 can be on a main circuit board, on a separate circuit board, or add-in card disposed within information handling system 1000, a device that is external to the information handling system, or a combination thereof.

Network interface 1080 represents a network communication device disposed within information handling system 1000, on a main circuit board of the information handling system, integrated onto another component such as chipset 1010, in another suitable location, or a combination thereof. Network interface 1080 includes a network channel 1082 that provides an interface to devices that are external to information handling system 1000. In a particular embodiment, network channel 1082 is of a different type than peripheral interface 1072 and network interface 1080 translates information from a format suitable to the peripheral channel to a format suitable to external devices.

In a particular embodiment, network interface 1080 includes a NIC or host bus adapter (HBA), and an example of network channel 1082 includes an InfiniBand channel, a Fibre Channel, a Gigabit Ethernet channel, a proprietary channel architecture, or a combination thereof. In another embodiment, network interface 1080 includes a wireless communication interface, and network channel 1082 includes a Wi-Fi channel, a near-field communication (NFC) channel, a Bluetooth® or Bluetooth-Low-Energy (BLE) channel, a cellular-based interface such as a Global System for Mobile (GSM) interface, a Code-Division Multiple Access (CDMA) interface, a Universal Mobile Telecommunications System (UMTS) interface, a Long-Term Evolution (LTE) interface, or another cellular based interface, or a combination thereof. Network channel 1082 can be connected to an external network resource (not illustrated). The network resource can include another information handling system, a data storage system, another network, a grid management system, another suitable resource, or a combination thereof.

BMC 1090 is connected to multiple elements of information handling system 1000 via one or more management interface 1092 to provide out-of-band monitoring, maintenance, and control of the elements of the information handling system. As such, BMC 1090 represents a processing device different from processor 1002 and processor 1004, which provides various management functions for information handling system 1000. For example, BMC 1090 may be responsible for power management, cooling management, and the like. The term BMC is often used in the context of server systems, while in a consumer-level device, a BMC may be referred to as an EC. A BMC included in a data storage system can be referred to as a storage enclosure processor. A BMC included at a chassis of a blade server can be referred to as a chassis management controller and embedded controllers included at the blades of the blade server can be referred to as blade management controllers. Capabilities and functions provided by BMC 1090 can vary considerably based on the type of information handling system. BMC 1090 can operate in accordance with an Intelligent Platform Management Interface (IPMI). Examples of BMC 1090 include an Integrated Dell® Remote Access Controller (iDRAC).

Management interface 1092 represents one or more out-of-band communication interfaces between BMC 1090 and the elements of information handling system 1000 and can include an Inter-Integrated Circuit (I2C) bus, a System Management Bus (SMBus), a Power Management Bus (PMBUS), a Low Pin Count (LPC) interface, a serial bus such as a USB or an SPI, a network interface such as an Ethernet interface, a high-speed serial data link such as a PCIe interface, a Network Controller Sideband Interface (NC-SI), or the like. As used herein, out-of-band access refers to operations performed apart from a BIOS/operating system execution environment on information handling system 1000, that is apart from the execution of code by processors 1002 and 1004 and procedures that are implemented on the information handling system in response to the executed code.

BMC 1090 operates to monitor and maintain system firmware, such as code stored in BIOS/EFI module 1042, option ROMs for graphics adapter 1030, disk controller 1050, add-on resource 1074, network interface 1080, or other elements of information handling system 1000, as needed or desired. In particular, BMC 1090 includes a network interface 1094 that can be connected to a remote management system to receive firmware updates, as needed or desired. Here, BMC 1090 receives firmware updates, stores the updates to a data storage device associated with the BMC, and transfers the firmware updates to the NVRAM of the device or system that is the subject of the firmware update, thereby replacing the currently operating firmware associated with the device or system, and reboots information handling system, whereupon the device or system utilizes the updated firmware image.

BMC 1090 utilizes various protocols and application programming interfaces (APIs) to direct and control the processes for monitoring and maintaining the system firmware. An example of a protocol or API for monitoring and maintaining the system firmware includes a graphical user interface (GUI) associated with BMC 1090, an interface defined by the Distributed Management Taskforce (DMTF) (such as a Web Services Management (WSMan) interface, a Management Component Transport Protocol (MCTP) or, a Redfish® interface), various vendor-defined interfaces (such as a Dell EMC Remote Access Controller Administrator (RACADM) utility, a Dell EMC OpenManage Enterprise, a Dell EMC OpenManage Server Administrator (OMSA) utility, a Dell EMC OpenManage Storage Services (OMSS) utility, or a Dell EMC OpenManage Deployment Toolkit (DTK) suite), a BIOS setup utility such as invoked by a “F2” boot option, or another protocol or API, as needed or desired.

In a particular embodiment, BMC 1090 is included on a main circuit board (such as a baseboard, a motherboard, or any combination thereof) of information handling system 1000 or is integrated into another element of the information handling system such as chipset 1010, or another suitable element, as needed or desired. As such, BMC 1090 can be part of an integrated circuit or a chipset within information handling system 1000. An example of BMC 1090 includes an iDRAC or the like. BMC 1090 may operate on a separate power plane from other resources in information handling system 1000. Thus BMC 1090 can communicate with the management system via network interface 1094 while the resources of information handling system 1000 are powered off. Here, information can be sent from the management system to BMC 1090 and the information can be stored in a RAM or NVRAM associated with the BMC. Information stored in the RAM may be lost after the power-down of the power plane for BMC 1090, while information stored in the NVRAM may be saved through a power-down/power-up cycle of the power plane for the BMC.

Information handling system 1000 can include additional components and additional busses, not shown for clarity. For example, information handling system 1000 can include multiple processor cores, audio devices, and the like. While a particular arrangement of bus technologies and interconnections is illustrated for the purpose of example, one of skill will appreciate that the techniques disclosed herein are applicable to other system architectures. Information handling system 1000 can include multiple central processing units (CPUs) and redundant bus controllers. One or more components can be integrated together. Information handling system 1000 can include additional busses and bus protocols, for example, I²C and the like. Additional components of information handling system 1000 can include one or more storage devices that can store machine-executable code, one or more communications ports for communicating with external devices, and various input and output (I/O) devices, such as a keyboard, a mouse, and a video display.

For purposes of this disclosure information handling system 1000 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 1000 can be a personal computer, a laptop computer, a smartphone, a tablet device or other consumer electronic device, a network server, a network storage device, a switch, a router, or another network communication device, or any other suitable device and may vary in size, shape, performance, functionality, and price. Further, information handling system 1000 can include processing resources for executing machine-executable code, such as processor 1002, a programmable logic array (PLA), an embedded device such as a System-on-a-Chip (SoC), or other control logic hardware. Information handling system 1000 can also include one or more computer-readable media for storing machine-executable code, such as software or data.

Although FIG. 8 shows example blocks of method 800 in some implementations, method 800 may include additional blocks, fewer blocks, different blocks, or differently arranged blocks than those depicted in FIG. 8. Those skilled in the art will understand that the principles presented herein may be implemented in any suitably arranged processing system. Additionally, or alternatively, two or more of the blocks of method 800 may be performed in parallel. For example, block 805 and decision block 810 of method 800 may be performed in parallel.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionalities as described herein.

When referred to as a “device,” a “module,” a “unit,” a “controller,” or the like, the embodiments described herein can be configured as hardware. For example, a portion of an information handling system device may be hardware such as, for example, an integrated circuit (such as an Application Specific Integrated Circuit (ASIC), a Field Programmable Gate Array (FPGA), a structured ASIC, or a device embedded in a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device).

The present disclosure contemplates a computer-readable medium that includes instructions or receives and executes instructions responsive to a propagated signal; so that a device connected to a network can communicate voice, video, or data over the network. Further, the instructions may be transmitted or received over the network via the network interface device.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding, or carrying a set of instructions for execution by a processor or that causes a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random-access memory or other volatile re-writable memory. Additionally, the computer-readable medium can include a magneto-optical or optical medium, such as a disk or tapes, or another storage device to store information received via carrier wave signals such as a signal communicated over a transmission medium. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or instructions may be stored.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents but also equivalent structures.

What is claimed is:

1. A printed circuit board comprising:
a coupled differential trace pair with a tabbed routing, wherein the coupled differential trace pair includes a differential trace pair; and
the differential trace pair comprising a trace, wherein the trace includes a skew compensation structure at a portion of the trace before the tabbed routing.

2. The printed circuit board of claim 1, wherein the trace is a microstrip.

3. The printed circuit board of claim 1, wherein the skew compensation structure is configured to lengthen the trace.

4. The printed circuit board of claim 1, wherein the skew compensation structure is configured to increase width of the trace.

5. The printed circuit board of claim 1, wherein the skew compensation structure is a serpentine structure.

6. The printed circuit board of claim 1, wherein the coupled differential trace pair includes another differential trace pair adjacent to the differential trace pair.

7. The printed circuit board of claim 6, wherein the another differential trace pair includes another trace with another skew compensation structure at another portion of the other trace before the tabbed routing.

8. An information handling system comprising:
a printed circuit board further comprising:
a coupled differential trace pair with a tabbed routing, wherein the coupled differential trace pair includes a differential trace pair; and
the differential trace pair comprising a trace, wherein the trace includes a skew compensation structure at a portion of the trace before the tabbed routing.

9. The information handling system of claim 8, wherein the trace is a microstrip.

10. The information handling system of claim 8, wherein the skew compensation structure is configured to lengthen the trace.

11. The information handling system of claim 8, wherein the skew compensation structure is configured to increase width of the trace.

12. The information handling system of claim 8, wherein the skew compensation structure is a serpentine structure.

13. The information handling system of claim 8, wherein the coupled differential trace pair include another differential trace pair adjacent to the differential trace pair.

14. The information handling system of claim 13, wherein the another differential trace pair includes another trace with another skew compensation structure at another portion of the other trace before the tabbed routing.

15. A method comprising:
determining, by a processor, a skew associated with a printed circuit board;
in response to determining that the printed circuit board includes a coupled differential trace pair with a tabbed routing, wherein the coupled differential trace pair include a differential trace pair; and
forming a skew compensation structure on a trace of the differential trace pair before the tabbed routing.

16. The method of claim 15, wherein the skew compensation structure is configured to lengthen the trace.

17. The method of claim 15, wherein the skew compensation structure is configured to increase width of the trace.

18. The method of claim 15, wherein the skew compensation structure is a serpentine structure.

19. The method of claim 15, wherein the coupled differential trace pair include another differential trace pair adjacent to the differential trace pair.

20. The method of claim 19, wherein the other differential trace pair includes a second trace with another skew compensation structure at a portion of the second trace before the tabbed routing.
